(19) United States
(12) Patent Application Publication
(10) Pub. No.: US 2012/0122273 A1
(43) Pub. Date: May 17, 2012

(54) DIRECT CURRENT ION IMPLANTATION FOR SOLID PHASE EPITAXIAL REGROWTH IN SOLAR CELL FABRICATION

(76) Inventors: Moon CHUN, San Jose, CA (US); Babak ADIBI, Los Altos, CA (US)

(21) Appl. No.: 13/299,292

(22) Filed: Nov. 17, 2011

Related U.S. Application Data
(60) Provisional application No. 61/414,588, filed on Nov. 17, 2010.

(51) Int. Cl. H01L 31/18

(52) U.S. Cl. 438/98; 438/57; 257/E31.113; 257/E31.11

(57) ABSTRACT

An apparatus and methods for ion implantation of solar cells. The disclosure provide enhanced throughput and recued or elimination of defects after SPER anneal step. The substrate is continually implanted using continuous high dose-rate implantation, leading to efficient defect accumulation, i.e., amorphization, while suppressing dynamic self-annealing.

### RELATED APPLICATIONS

This application claims priority benefit from U.S. Provisional Patent Application, Ser. No. 61/414,588, filed Nov. 17, 2010, the disclosure of which is incorporated herein by reference in its entirety.

### BACKGROUND

1. Field

This invention relates to ion implantation and, especially, to ion implantation for fabrication of solar cells at high throughput and low defect level.

2. Related Arts

Ion implantation has been used in the manufacture of semiconductors for many years. A typical commercial device has a generally an ion beam that is scanned over the substrate, by either moving the beam, the substrate, or both. In one example a “pencil” beam is scanned in x and y directions over the entire surface of the substrate, while another example uses a “ribbon” beam of width slightly wider than the substrate, so that scanning is done in only one direction to cover the entire substrate. In addition to being very slow, these two systems have inherent problem relating to generation of defects. That is, considering a single point on the substrate, the ion implant from any of these two systems appears to be pulsed, even though the beam is energized continuously. That is, each point on the substrate “sees” the ion beam for a short period, and then “waits” for the next scan of the beam. This causes localized heating, which leads to creation of extended defects due to dynamic self-annealing between scans.

Recently, another method has been proposed for ion implantation, generally referred to as plasma immersion ion implantation, or P3i. In such processing chambers, rather than using a beam of ions, plasma is created above the entire substrate. Then, AC potential, generally in the form of RF power, is coupled to the substrate so as to attract ions from the plasma into the substrate. Consequently, from the substrate perspective, such systems also operate in “pulsed” mode and lead to the same self-annealing problem exhibited by ion-beam based systems.

One type of defects, generally caused by end-of-range damage, presents a consistent problem with traditional ion implantation systems. Self-annealing resulting from the localized heating and subsequent cooling leads to cluster defects that cannot be eliminated during the subsequent anneal step. Accordingly, what is needed in the art is an ion implantation system and method that enables high speed implantation while avoiding defects.

### SUMMARY

The following summary is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Disclosed embodiments provide ion implantation methods that enable high throughput fabrication of solar cells, while minimizing or eliminating defects. Using various experimentation conditions, it has been shown that the disclosed method is superior to prior art ion implantation method, especially for eliminating defect clusters caused by end-of-range damage.

According to disclosed embodiments, ion implantation is performed using continuous ion implantation at high dose rate. The ion implantation is performed concurrently over the entire surface of the substrate, or the areas chosen for selective ion implantation (e.g., for a selective emitter design). The implant energy may be, for example, 5-100 keV, or more specifically, 20-40 keV, while the dose rate is at the level of, e.g., higher than 1E¹⁴ or even higher than 1 E¹⁵ ions/cm⁻²/second, and in some embodiments in the range of 1E¹⁴-5E¹⁶ ions/cm⁻²/second. The high dose rate enabled high throughput while fully amorphizing the implanted layer of the substrate. Since the implantation was continuous, no self-annealing occurred and no defect clusters were observed. After anneal, the amorphous layer fully crystalized and no defects clusters were observed.

According to another aspect of the invention, a method for fabrication of solar cell using ion implantation is provided. According to the method, substrate is introduced into an ion implantation chamber. A beam of the ion species is generated, having cross-section that is sufficiently large to cover the entire surface of the substrate. Ions from the beam are continuously accelerated towards the surface of the substrate, so as to continually implant ions into the substrate. The dose rate is designed so as to completely amorphize a designated layer of the substrate. Optionally, further processing is performed, such as the deposition of anti-reflection or encapsulation layer, e.g., silicon nitride layer, and deposition of metallization grid. The substrate is then annealed so as to re-crystallize the amorphous layer and activate the dopant ions that were implanted. According to one embodiment, the anneal step is performed using rapid thermal processing, e.g., at about 600-1000° C. for a few seconds, e.g., 1-20 seconds, or in one specific example for five seconds.

According to another embodiment of the invention, a method of ion implantation is provided, which can be used for the fabrication of solar cells. According to the embodiment, a substrate is introduced into an ion implantation chamber. The areas of the substrate selected to be implanted are then continuously bombarded with ions, such that the areas are amorphized without possibility of self-annealing. The substrate is annealed in a rapid thermal processing chamber utilizing solid phase epitaxial re-growth.

Aspect of the invention includes a method for fabricating solar cells using ion implantation, comprising: introducing a substrate into an ion implantation chamber; generating a continuous stream of ions to be implanted in the substrate; and directing the stream of ions toward the surface of the substrate to cause continuous ion bombardment of the surface of the substrate to thereby implant ions into the substrate while amorphizing a layer of the substrate.

Further aspects of the invention include a method for ion implantation of a substrate, comprising: introducing a substrate into an ion implantation chamber; generating a continuous stream of ions to be implanted in the substrate; and directing the stream of ions toward the surface of the substrate to cause continuous ion bombardment of the surface of the substrate while preventing self-anneal of the substrate.

Other aspects of the invention include a method for ion implantation of a substrate, comprising: introducing a substrate into an ion implantation chamber; generating a continuous stream of ions to be implanted in the substrate; and directing the stream of ions toward the surface of the substrate to cause continuous ion bombardment of the surface of the substrate to thereby amorphize the entire surface of the substrate simultaneously.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 is a plot comparing instantaneous ion implant dose of prior art and disclosed method.

FIG. 2 is a plot of defects after annealing vs. dose rate for the prior art implanter and the current embodiment.

FIG. 3A is a micrograph of a wafer after ion implantation according to one embodiment, while FIG. 3B is the wafer after anneal at 930° C. for 30 minutes in a conventional furnace.

FIG. 4 is a schematic illustrating an ion implantation chamber that can be used for the method described herein.

### DETAILED DESCRIPTION

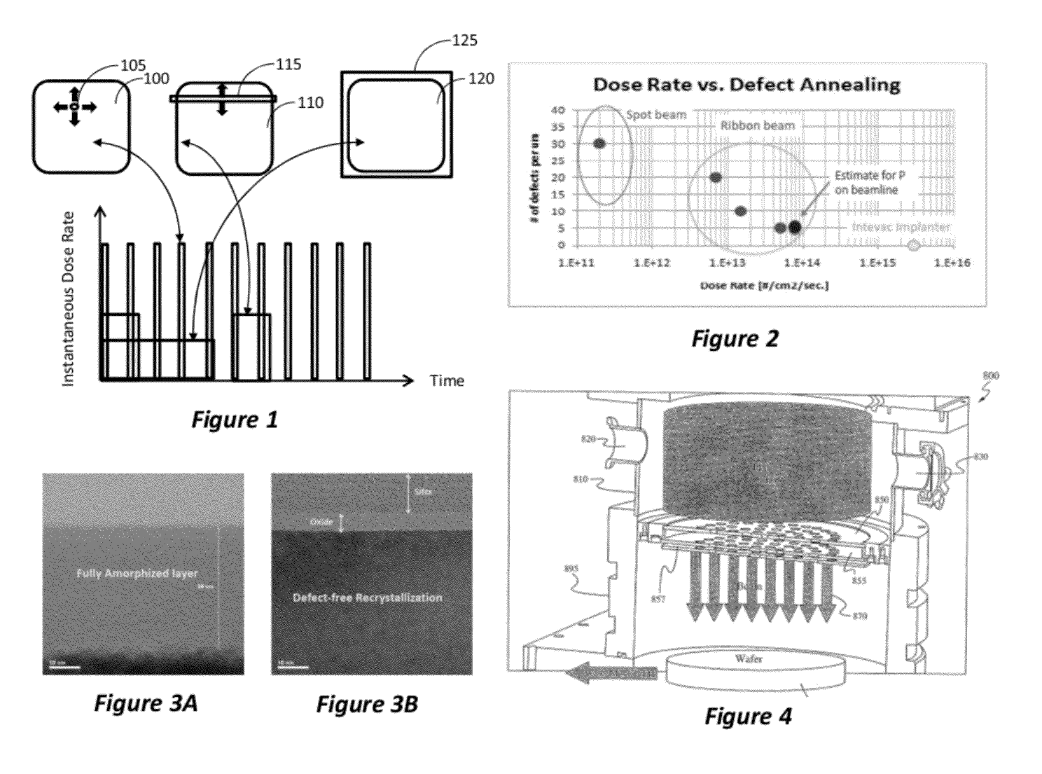

FIG. 1 is a plot comparing instantaneous ion implant dose of prior art and the disclosed method. As illustrated, wafer 100 is implanted by using a “pencil” beam 105 that is scanned two-dimensionally to cover the wafer. The resulting instantaneous dose rate at each point on the substrate is plotted as periodic implantation at high instantaneous dose rate, but for very short time duration. This causes localized heating, followed by self-annealing and defect clusters. Similarly, wafer 110 is implanted using a ribbon beam 115 that is scanned in one direction to cover the wafer. The resulting instantaneous dose rate at each point on the substrate is plotted as periodic implantation at moderately-high instantaneous dose rate, but for short time duration. This also causes localized heating, followed by self-annealing and defect clusters. Conversely, according to one embodiment, wafer 120 is implanted using a continuous flux of beam 125, such that each point to be implanted (here the entire wafer) is continuously implanted with ions and no self-annealing occurs.

As can be appreciated, the total dose rate plotted in FIG. 1 can be arrived at by integrating the plots of the various methods. One can set the systems such that the integrated dose rate is equal to all three systems, however, the instantaneous dose rate at each point on the wafer would be highest for the pencil beam, somewhat lower for the ribbon, and lowest for the “constant-on” beam of the current embodiment. Consequently, the integrated dose rates of the pencil and ribbon beam are limited so as not to overheat the wafer. On the other hand, the constant-on beam of this embodiment can have much higher average dose rate and still maintain the wafer at an acceptable temperature. For example, in some embodiments, the dose rate was set at higher than 1E15 ions/cm⁻²/second. In one example, the implant conditions were set to: implant energy of 20 keV and dose of 3E15 cm⁻².

Referring now to FIG. 2, the advantage of the disclosed method is evident from the plot. FIG. 2 is a plot of the number of defects after annealing vs. the dose rate for the prior art implanter and the current embodiment. In FIG. 2, the current embodiment is indicated as “Intevac implanter.” As can be appreciated from the plot of FIG. 2, the pencil beam ion implantation results in the highest number of defect remaining after the anneal process, while the disclosed method results in the least, or no defects remaining after the anneal process. Also, the difference in the number of defects shown in the plot further supports the postulation that the defects are caused by the self-annealing mechanism, which does not exists using the disclosed method.

Moreover, FIG. 2 indicates that the annealing mechanism improves with increased average dose rate. This may indicate that defects accumulate more efficiently with increase in dose rate, but can be annealed better as the average dose rate increasers. Also, since the substrate has no opportunity for self-anneal when continuously implanted, the disclosed method provides a better amorphization of the substrate.

In the embodiments described above, the substrate may be annealed using conventional furnace or a rapid thermal process (RTP). In one example, the wafers were annealed in a furnace at temperature of, e.g., 930° C. for about 30 minutes, while using RTP the wafers were annealed at temperatures of 600-1000° C. for about 1-10 second, and in specific examples for 5 seconds. Notably, investigation of a beam-line implanted and conventionally annealed samples showed that an oxide layer was added. Specifically, a Rutherford Backscattering Spectrometry (RBS) showed a broadened silicon peak, indicating residual damage after anneal. Conversely, the RBS plot for RTP annealed wafer according to the disclosed method showed neither oxide nor broadening of silicon peak, indicating that the sample has completely recrystallized.

FIG. 3A is a micrograph of a wafer after ion implantation according to one embodiment, while FIG. 3B is a micrograph of the wafer after anneal at 930° C. for 30 minutes in a conventional furnace. The implant was performed using a PH₃ source gas at 20 keV and 3E15 cm⁻². As can be seen in the micrograph of FIG. 3A, the implanted layer is fully amorphized. Also, the micrograph of FIG. 3B shows defect-free fully-recrystallized layer.

FIG. 4 illustrates a cross-sectional 3-dimensional perspective view of an embodiment of a plasma grid implant system 800, which can be used for the disclosed method. System 800 comprises a chamber 810 that houses a first grid plate 850, a second grid plate 855, and a third grid plate 857. The grid plates can be formed from a variety of different materials, including, but not limited to, silicon, graphite, silicon carbide, and tungsten. Each grid plate comprises a plurality of apertures configured to allow ions to pass therethrough. A plasma source sustains plasma at a plasma region of the chamber 810. In FIG. 4, this plasma region is located above the first grid plate 850. In some embodiments, a plasma gas is fed into the plasma region through a gas inlet 820. The plasma gas may be a combination of plasma sustaining gas, such as argon, and doping gas, such as gases containing phosphorus, boron, etc. Additionally, non-dopant amorphizing gas may also be included, such as, e.g., germanium. In some embodiments, a vacuum is applied to the interior of the chamber 810 through a vacuum port 830. In some embodiments, an insulator 895 is disposed around the exterior wall of the chamber 810. In some embodiments, the chamber walls are configured to repel ions in the plasma region using an electric and/or magnetic field, e.g., from permanent or electro-magnets.

A target wafer 840 is positioned on the opposite side of the grid plates from the plasma region. In FIG. 4, the target wafer 840 is located below the third grid plate 857. The target wafer 840 is supported by an adjustable substrate holder, thereby allowing the target wafer 840 to be adjusted between a homogeneous implant position (closer to the grid plates) and a selective implant position (farther away from the grid plates). Plasma ions are accelerated in the form of ion beams 870 towards the target wafer 840, by application of a DC potential to the first grid plate 850. These ions are implanted into the wafer 840. The deleterious effect of secondary electrons resulting from the impingement of ions on the wafer 840 and other materials is avoided through the use of the second grid plate 855, which is negatively-biased with respect to the initial grid. This negatively-biased second grid plate 855 suppresses the electrons that come off of the wafer 840. In some embodiments, the first grid plate 850 is biased to 80 kV and the second grid plate 855 is biased to −2 kV. However, it is contemplated that other biasing voltages can be employed. The third grid plate 857 acts as a beam defining grid and is generally grounded. It is positioned in contact with or very close to the surface of the substrate in order to provide a final definition of the implant. This grid plate 857 can act as a beam defining mask and provide the critical alignment required, if a selective implant is required. The third grid plate 857 can be configured as a shadow mask in order to achieve beam-defining selective implantation. Additionally, the third grid plate 857 can be replaced or supplemented with any form of beam shaping that does not require a mask.

In the embodiment of FIG. 4, the ions are extracted from the plasma zone and are accelerated towards the substrate. When the substrate is sufficiently spaced from the grid plates, the ion beams 870 have sufficient travel distance so as to form one column of ions traveling towards the substrate. This is caused by the natural divergence tendency of each ion beam 870 once it exits the grid plate. The uniformity over the cross-section of the ion column can be controlled by, among others, the number, size, and shape of the holes in the grid plates, the distance between the grid plataes, and the distance between the grid plates and the substrate. It should be noted that while in the embodiment of FIG. 4 the grid plates and/or the substrate is used to control the generation of ion column and its uniformity, other means can be used. The main goal is to generate a single column of ions, wherein the column has cross-section sufficiently large to enable implanting the entire surface of the substrate concurrently and continuously. Of course, if selective implantation is performed, the third grid plate can be used to block parts of the column.

As can be understood from the above, embodiments of the method proceed by introducing a substrate into an ion implanter, generating an ion beam or column of cross-section size sufficiently large to cover the entire area of the substrate, and directing the beam so as to continuously implant ions onto the substrate and amorphize a layer of the substrate. To improve throughput, the substrate is then annealed in an RTP chamber, utilizing the SPER anneal mechanism, wherein the amorphous layer re-crystallizes. This anneal step also activates the dopants that were implanted from the ion beam. According to another embodiment utilized for fabrication of solar cells, after ion implantation further layers of the solar cell are fabricated over the amorphized layer, including a metallization layer. Then the substrate is transferred into the RTP chamber to anneal the metallization layer and the amorphized layer concurrently. That is, the SPER anneal is achieved using the metallization anneal step, so that there is no separate anneal step after the ion implant process.

While this invention has been discussed in terms of exemplary embodiments of specific materials, and specific steps, it should be understood by those skilled in the art that variations of these specific examples may be made and/or used and that such structures and methods will follow from the understanding imparted by the practices described and illustrated as well as the discussions of operations as to facilitate modifications that may be made without departing from the scope of the invention defined by the appended claims.

1. A method for fabricating solar cells using ion implantation, comprising:
introducing a substrate into an ion implantation chamber;
generating a continuous stream of ions to be implanted in the substrate;
directing the stream of ions toward the surface of the substrate to cause continuous ion bombardment of the surface of the substrate to thereby implant ions into the substrate while amorphizing a layer of the substrate.

2. The method of claim 1, wherein the step of generating a continuous stream of ion comprises generating a beam of ions having a cross section sufficiently large to enable simultaneous implantation over the entire surface of the substrate.

3. The method of claim 1, further comprising:
defining an area of the substrate to be implanted; and,
wherein the step of generating a continuous stream of ion comprises generating a beam of ions having a cross section sufficiently large to enable simultaneous implantation over the entire area of the substrate to be implanted.

4. The method of claim 1, wherein the step of generating a continuous stream of ion comprises:
sustaining plasma using gas containing species to be implanted;
extracting a beam of ions of said species, wherein the beam has a cross section sufficiently large to enable simultaneous implantation over the entire surface of the substrate.

5. The method of claim 1, wherein the implant energy is 5-100 keV.

6. The method of claim 1, wherein the implant energy is 20-40 keV.

7. The method of claim 1, wherein the dose rate is higher than 1 E¹⁵ ions/cm⁻²/second.

8. The method of claim 2, further comprising annealing the substrate using rapid thermal processing.

9. The method of claim 8, wherein the annealing is performed at 600-1000° C. for about 1-10 seconds.

10. The method of claim 1, further comprising:
subsequent to the ion implantation process, and without performing an anneal step, fabricating a metallization layer on the substrate; and,
subsequent to forming the metallization layer annealing the substrate to simultaneously anneal the metallization layer, recrystallize the amorphized layer, and activate implanted dopants.

11. A method for ion implantation of a substrate, comprising:
introducing a substrate into an ion implantation chamber;
generating a continuous stream of ions to be implanted in the substrate;
directing the stream of ions toward the surface of the substrate to cause continuous ion bombardment of the surface of the substrate while preventing self-anneal of the substrate.

12. The method of claim 11, wherein preventing self-anneal of the substrate comprises causing continuous bombardment of ion species over the entire surface to be implanted.

13. The method of claim 12, further comprising completely amorphizing a layer of the substrate to be implanted.

14. The method of claim 12, wherein the entire front surface of the substrate is implanted simultaneously.

15. The method of claim 11, wherein the step of generating a continuous stream of ion comprises:
sustaining plasma using gas containing species to be implanted;
extracting a column of ions of said species, wherein the column has a cross section sufficiently large to enable simultaneous implantation over the entire surface of the substrate.

16. The method of claim 15, wherein the step of extracting a column of ions comprises extracting a plurality of ion beams from the plasma and enabling the plurality of ion beams to combine inot a single column of ions.

17. The method of claim 16, wherein the implant energy is 5-100 keV.

18. The method of claim 16, wherein dose rate is designed so as to completely amorphize a designated layer of the substrate.

19. The method of claim 18, wherein the dose rate is higher than 1 E¹⁵ ions/cm⁻²/second.

20. The method of claim 18, wherein the average dose is 5E14-5E16 cm⁻².

21. A method for ion implantation of a substrate, comprising:
introducing a substrate into an ion implantation chamber;
generating a continuous stream of ions to be implanted in the substrate;
directing the stream of ions toward the surface of the substrate to cause continuous ion bombardment of the surface of the substrate to thereby amorphize the entire surface of the substrate simultaneously.

22. The method of claim 21, wherein the step of generating a continuous stream of ion comprises:
sustaining plasma using gas containing species to be implanted;
extracting a column of ions of said species, wherein the column has a cross section sufficiently large to enable simultaneous implantation over the entire surface of the substrate.
